(19) United States
(12) Patent Application Publication
(10) Pub. No.: US 2024/0291393 A1
(43) Pub. Date: Aug. 29, 2024

(54) COMMUTATION CELL FOR AN INVERTER

(71) Applicant: ROBERT BOSCH GMBH, Stuttgart (DE)

(72) Inventors: Balazs Bence HARSANYI, Bietigheim-Bissingen (DE); Dominilk Alexander Ruoff, St. Johann (DE); Gerhard Braun, Rottenburg (DE); Sebastian Strache, Wannweil (DE); Tobias Zahn, Rottenburg (DE)

(21) Appl. No.: 18/572,368

(22) PCT Filed: Jun. 24, 2022
(86) PCT No.: PCT/EP2022/067325

§ 371 Date: Dec. 20, 2023

(30) Foreign Application Priority Data
Jun. 25, 2021 (DE) 10 2021 206 621.6

(51) Int. Cl. H02M 7/00; H02M 1/00; H02M 7/5387

(52) U.S. Cl. CPC H02M 7/003; H02M 1/0009; H02M 7/5387

(57) ABSTRACT

A commutation cell for an inverter. The commutation cell includes a ceramic circuit carrier, and a semiconductor switch half bridge. The commutation cell also includes a current sensor, which is designed and arranged for detecting a phase current of the commutation cell. The commutation cell includes a flexible circuit board, which is in particular integrally bonded to the circuit carrier and is arranged parallel to the circuit carrier. The circuit carrier includes a conducting track, which is designed to conduct the output current of the half bridge. The current sensor is electrically connected to the flexible circuit board and arranged to detect a magnetic field generated by the conducting track through which in particular current flows, and is designed to generate a current signal that represents the current flowing in the conducting track.

### FIELD

The present invention relates to a commutation cell, in particular for an inverter. The commutation cell comprises an in particular ceramic circuit carrier, and a semiconductor switch half bridge. The commutation cell also comprises a current sensor which is designed and arranged to detect a phase current of the commutation cell.

### BACKGROUND INFORMATION

German Patent Application No. DE 10 2011 003 998 B4 describes an integrated circuit comprising a semiconductor chip and a magnetic field sensor, the magnetic field sensor being designed to detect a magnetic field generated by a current flowing through the sintered metal layer.

### SUMMARY

According to the present invention, the commutation cell comprises a flexible circuit board, which is in particular integrally bonded to the circuit carrier and is arranged parallel to the circuit carrier. The circuit carrier comprises a conducting track, which is designed to conduct the output current of the half bridge. The current sensor is electrically connected to the flexible circuit board and arranged to detect a magnetic field generated by the conducting track through which in particular current flows, and is designed to generate a current signal that represents the current flowing in the conducting track. Advantageously, a structure that is stable in particular against thermal expansions can thus be formed by means of the flexible circuit board. Advantageously, the magnetic field to be detected by the current sensor can be conducted through the flexible circuit board so that the current sensor can be mechanically and electrically connected to the flexible circuit board in a cost-effective manner.

Preferably, according to an example embodiment of the present invention, the current sensor is soldered, sintered, or glued by means of an electrically conductive adhesive to the flexible circuit board. Advantageously, the commutation cell and the current sensor can in this way be formed in a cost-effective manner.

In a preferred embodiment of the present invention, the flexible circuit board and the circuit carrier are integrally bonded to one another lying flat on top of one another. The integral bond between the flexible circuit board and the circuit carrier is preferably formed by a solder connection or an adhesive connection. Advantageously, in this way, a layer composite can be formed, which can be produced in a cost-effective manner.

In a preferred embodiment of the present invention, the conducting track is S-shaped in the region of the circuit carrier. Advantageously, a magnetic field gain for detecting the current in the conducting track can be formed in this way.

In a preferred embodiment of the present invention, the conducting track is I-shaped in the region of the circuit carrier. Advantageously, the conducting track can thus have two recesses which enclose the I-shaped conducting track between one another and through which a magnetic field can be conducted for detection by the current sensor.

In a preferred embodiment of the present invention, the commutation cell comprises a shielding element. The shielding element is preferably formed between the current sensor and the conducting track. Advantageously, an electrical field generated by the conducting track of the in particular ceramic circuit carrier thus cannot scatter into conducting tracks of the flexible circuit board or into electrical components connected to the flexible circuit board.

In a preferred embodiment of the commutation cell of the present invention, the shielding element is formed by an electrically conductive layer of the flexible circuit board. Advantageously, the shielding element can thus be provided in a cost-effective manner as a component of the flexible circuit board.

In a preferred embodiment of the present invention, the current sensor is formed by an in particular differential Hall sensor, wherein the Hall sensor comprises two sensor elements. The current sensor is preferably formed by a component designed for surface mounting with the flexible circuit board. The current sensor is preferably formed by a semiconductor without a housing, also known as a bare die.

The current sensor can thus advantageously be connected to the flexible circuit board in a cost-effective manner, in particular by means of reflow soldering.

In a preferred embodiment of the present invention, the conducting track of the in particular ceramic circuit carrier has two recesses adjacent to one another. Further preferably, the shielding element has recesses which correspond to the recesses and are arranged one above the other with the recesses of the conducting track, in particular in an orthogonal projection. Advantageously, in this way, two slots can be formed under the sensor cells so that magnetic field propagation of the magnetic field generated by the busbar is possible in the slots. Further advantageously, a capacitive coupling due to parasitic capacitances between the current conductor and the current sensor, and thus a coupling into a signal guide on the flexible circuit board, can be largely inhibited or prevented by the shielding element, in particular a shielding layer.

In a preferred embodiment of the present invention, signal lines routed to the sensor are shielded by the shielding element. Advantageously, in this way, a capacitive coupling due to parasitic capacitances between the current conductor and the signal guide in the signal lines can be prevented.

In a preferred embodiment of the present invention, the shielding element is formed by an electrically conductive layer, in particular an inner layer, of the flexible circuit board, which is insulated from the conducting track, or additionally from the current sensor, by at least one, or two, electrically insulating layers surrounding the circuit board.

The flexible circuit board, in particular FCB (FCB=flexible circuit board), preferably comprises at least one electrically conductive layer, in particular a rewiring layer, and at least one electrically insulating layer, in particular a polyimide layer, PVB layer (PVB=polyvinyl butyral, EVA layer (EVA=ethylene vinyl acetate), or PVF layer (PVF=polyvinyl fluoride).

The flexible circuit board is preferably designed to be reversibly bendable in such a way that the circuit board can be bent without breaking. The flexible circuit board is preferably designed to be flexible or resilient in such a way that the circuit board can be bent at least at a right angle or in a U-shape without breaking. Advantageously, an in particular vibration-resistant connection can in this way be formed in a cost-effective manner between the circuit carrier and the circuit board.

The electrically insulating layer of the flexible circuit board is preferably designed to electrically insulate voltage-carrying conducting tracks of the circuit carrier, in particular high-voltage conducting tracks, from the at least one electrically conductive layer of the flexible circuit board, in particular low-voltage rewiring layer.

The present invention also relates to an inverter with a commutation cell of the type described above. The inverter has at least three phases for providing current to an electric machine, wherein at least one commutation cell is formed on the inverter for each of the phases. The commutation cell preferably comprises at least one semiconductor switch half bridge comprising a high-side semiconductor switch and a low-side semiconductor switch.

The present invention is explained in more detail below with reference to figures and further exemplary embodiments. Further advantageous embodiment variants result from a combination of the features disclosed herein.

### BRIEF DESCRIPTION OF THE DRAWINGS

FIG. 1 shows an exemplary embodiment of a commutation cell for an inverter, according to the present invention.

FIG. 2 shows a plan view of the commutation cell shown in FIG. 1.

### DETAILED DESCRIPTION OF EXAMPLE EMBODIMENTS

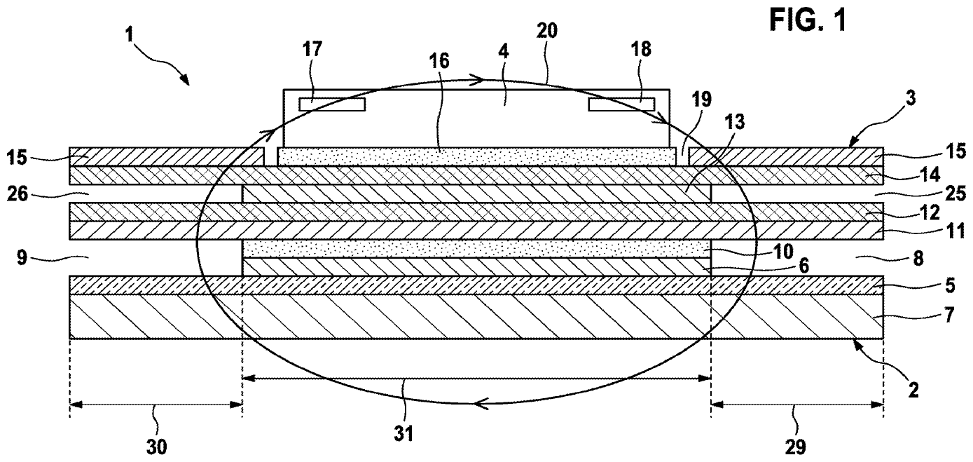

FIG. 1 shows an exemplary embodiment of the present invention of a commutation cell for an inverter, in which commutation cell a flexible circuit board and a circuit carrier are connected to one another lying flat on top of one another, and a current sensor is arranged on the flexible circuit board to detect a current flowing in the circuit carrier, depending on a magnetic field generated by the current, wherein a magnetic field generated by a conducting track of the circuit carrier can reach the current sensor through recesses in a shielding layer.

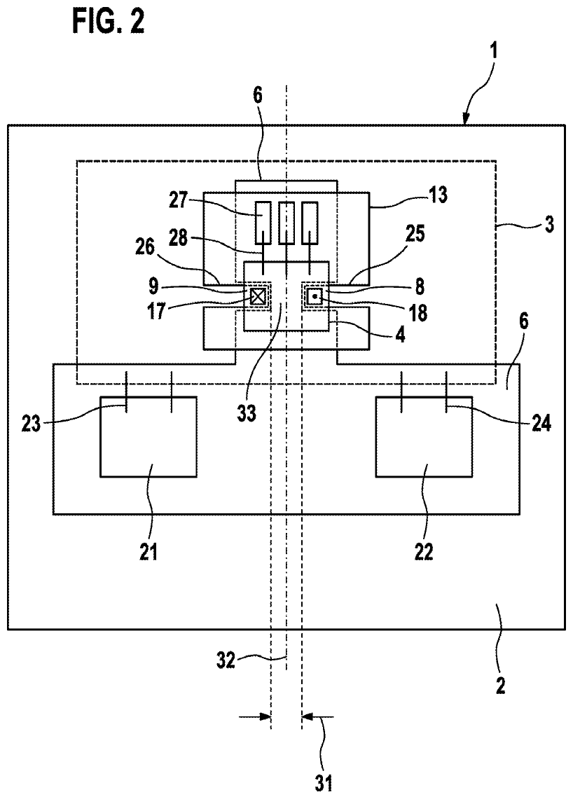

FIG. 2 shows a plan view of the commutation cell shown in FIG. 1.

FIG. 1 shows, schematically, a sectional view of an exemplary embodiment of a commutation cell 1 for an inverter. The commutation cell 1 comprises a circuit carrier 2 which in this exemplary embodiment is designed as a ceramic circuit carrier, and for this purpose comprises an electrically insulating ceramic layer 5, in particular an aluminum oxide layer or silicon nitride layer. The circuit carrier 2 is, for example, an AMB circuit carrier (AMB=active metal brazed, an IMS circuit carrier (IMS=insulated metal substrate), or a DCB circuit carrier (DCB=direct copper bonded). The circuit carrier 2 also comprises an electrically conductive layer 6, in particular a copper layer, for rewiring, which in this exemplary embodiment forms an output connection of a semiconductor switch half bridge (shown in more detail in FIG. 2). The circuit carrier 2 also comprises a rear-side contacting 7, which in this exemplary embodiment is formed by a copper layer, and which can be connected in a thermally conductive manner to a heat sink. A layer thickness of the ceramic layer is, for example, between 100 and 500 micrometers, and a layer thickness of the rewiring layer and of the rear-side layer is, for example, between 150 and 800 micrometers in each case.

The commutation cell 1 also comprises a flexible circuit board 3. In this exemplary embodiment, the flexible circuit board 3 comprises a plurality of electrically conductive layers, in particular copper layers, and electrically insulating layers, in particular polyimide layers. The electrically insulating layers have, for example, a thickness extension of between 40 and 100 micrometers, in this exemplary embodiment 60 micrometers. In this exemplary embodiment, the electrically conductive layers have a thickness extension between 15 and 50 micrometers.

The flexible circuit board 3 comprises an electrically conductive rear-side layer 11, in this exemplary embodiment a copper layer, which is designed for integral bonding to the circuit carrier 2. In this exemplary embodiment, the electrically conductive rear-side layer 11 has a layer thickness of 18 micrometers. The flexible circuit board 3 also comprises an electrically insulating layer 12, in particular a polyimide layer, which is bonded to the electrically conductive layer 11, in particular by means of lamination, so that they lie on top of one another. The flexible circuit board 3 also comprises an electrically conductive shielding layer 13, in particular a copper layer, which is bonded to the electrically insulating layer 12 in particular by means of lamination, and, together with the electrically conductive layer 11, encloses the electrically insulating layer 12 between them, in particular in the manner of a sandwich.

On the side facing away from the electrically insulating layer 12, the electrically conductive shielding layer 13 is bonded to a further electrically insulating layer 14 so that the further electrically insulating layer 14 and the electrically insulating layer 12 enclose the shielding layer 13 between them, in particular in the manner of a sandwich, and thus together form a layer composite of layers arranged flat on top of one another.

The flexible circuit board 3 also comprises an electrically conductive top layer 15, which in this exemplary embodiment forms a rewiring layer. The electrically conductive layer 15 is bonded to the further electrically insulating layer 14 in particular by means of lamination.

The flexible circuit board 3 is integrally bonded to the circuit carrier 2 by means of a solder material 10. Instead of the solder material, the flexible circuit board 3 can also be bonded to the circuit carrier 2 by means of an in particular electrically conductive adhesive or by means of a gel, in particular a silicone gel.

In this exemplary embodiment, the electrically conductive layer 6 of the circuit carrier 2 is formed along a width portion 31 of the circuit carrier 2, on the sides of which the electrically conductive layer 6 has a recess 8 and a recess 9, respectively, in the sectional view shown in FIG. 1. The electrically conductive layer 6 is thus constricted by means of the recesses 8 and 9 so that a current which flows perpendicularly to the sectional plane shown in FIG. 1 in the electrically conductive layer 6 can generate a magnetic field 20 which extends with a perpendicular component in the recesses 8 and 9.

In this exemplary embodiment, the flexible circuit board 3 is connected to a magnetic field sensor 4. For this purpose, the magnetic field sensor 4, which in this exemplary embodiment is a component of the commutating cell 1, is bonded to the further electrically insulating layer 14 by means of a bonding agent 16, for example an adhesive or a soldering material. The flexible circuit board 3 has a recess 19 in the region of the magnetic field sensor 4, wherein the recess 19 is formed in the electrically conductive layer, in particular rewiring layer 15. The magnetic field sensor 4 is thus inserted into a recess of the rewiring layer 15.

In this exemplary embodiment, the magnetic field sensor 4 comprises two Hall sensors 17 and 18, which are each embedded or accommodated in a housing or in a solid material of the magnetic field sensor 4. The Hall sensors 17 and 18 are each designed and arranged to detect a perpendicular component of the magnetic field 20 and, in particular, to each generate, by means of difference formation, an electrical output signal that represents the magnetic field strength of the magnetic field 20.

The magnetic field sensor 4 is arranged in the region of the width portion 31, in an orthogonal projection, above the electrically conductive layer 6 so that, around the electrically conductive layer 6, which in this exemplary embodiment forms an electrical flat conductor, wherein circumferential magnetic field lines of the magnetic field 20 run through the Hall sensors 17 and 18.

The flexible circuit board 3 has two recesses 25 and 26 in the region of the shielding layer 13, which recesses are aligned with the recess 8 and the recess 9, respectively, in particular in an orthogonal projection. The recesses 8 and 25 extend along the width portion 29, and the recesses 26 and 9 extend along the width portion 30. The width portions 29 and 30 are arranged adjacent to the width portion 31 on opposite sides.

The magnetic field lines 20 can thus pass through the recesses 25 and 26 and are thus not impeded by the shielding layer 13. The shielding layer 13 is designed to adequately shield an electric field generated by the electrically conductive layer 6, from the current sensor 4.

FIG. 2 shows a plan view of the commutation cell 1 already shown in FIG. 1. The commutation cell 1 comprises two semiconductor switches 21 and 22, which together form a semiconductor switch half bridge. For example, the semiconductor switch 21 is a low-side semiconductor switch of the semiconductor switch half bridge, and the semiconductor switch 22 is a high-side semiconductor switch of the semiconductor switch half bridge. The semiconductor switches 21 and 22 are each electrically connected to the electrically conductive layer 6, in each case with a switching path connection, so that the electrically conductive layer 6 forms an output connection of the half bridge formed by the semiconductor switches 21 and 22.

In this exemplary embodiment, the electrically conductive layer 6 is T-shaped, wherein the output current can flow on a T-bar on which the constrictions formed by the recesses 8 and 9 are formed. The flexible circuit board 3 is arranged in the region of the recesses 8 and 9 in such a way that the recess 25 in the shielding layer 13 of the flexible circuit boards is aligned with the recess 8 in the electrically conductive layer 6 of the circuit carrier 2, in particular in an orthogonal projection.

In this exemplary embodiment, the output current of the semiconductor switch half bridge can flow in the electrically conductive layer along a longitudinal extension 32 on a web 33 formed between the recesses 8 and 9. In the sectional view shown in FIG. 1, the web 33 extends along the width portion 31.

In this exemplary embodiment, the flexible circuit board 3 comprises an electrically conductive rewiring layer 27 as the top layer, which is electrically conductively connected to the current sensor 4 by means of a bonding wire 28. In another embodiment, the current sensor 4 is designed as an SMD component and is designed for surface soldering to the rewiring layer.

For its controlling, the semiconductor switch 21 is electrically connected to the flexible circuit board 3 by means of bonding wires, of which one bonding wire 23 is designated as an example. The semiconductor switch 22 is electrically connected to the flexible circuit board 3 by means of bonding wires, of which one bonding wire 24 is designated as an example. The flexible circuit board 3 can thus form a control level, in which low-voltage signals for controlling the semiconductor switches 21 and 22 as well as sensor signals of the magnetic field sensor 4 flow, for the commutation cell 1.

In this exemplary embodiment, the circuit carrier 2 can form a high-voltage level in which electrical potential switched by the semiconductor switches 21 and 22 can be formed.

By means of the shielding layer 13, an electric field extending between the high-voltage level, formed by the circuit carrier 2, and the low-voltage level, formed by the flexible circuit board 3, can be adequately shielded. The field lines of the magnetic field 20 to be detected by the magnetic field sensor 4 can propagate sufficiently in the recesses 8, 9 of the electrically conductive layer 6 and in the recesses 25 and 26 respectively arranged parallel thereto, so that the Hall sensors 17 and 18 can detect the magnetic field 20.

Instead of the I-shape of the electrically conductive layer shown in FIG. 2 and formed by means of the recesses 8 and 9, an S-shape for current detection or a W-shape for current detection can also be formed instead of the I-shape.

1-10. (canceled)

11. A commutation cell, comprising:
a ceramic circuit carrier;
a semiconductor switch half bridge;
a current sensor configured and arranged to detect a phase current of the commutation cell; and
a flexible circuit board integrally bonded to the circuit carrier and arranged parallel to the circuit carrier;
wherein the circuit carrier includes a conducting track which is configured to conduct output current of the half bridge, and the current sensor is electrically connected to the flexible circuit board and is arranged to detect a magnetic field generated by the conducting track, through which current flows, and is configured to generate a current signal that represents the current flowing in the conducting track.

12. The commutation cell according to claim 11, wherein the flexible circuit board and the circuit carrier are integrally bonded to one another lying flat on top of one another.

13. The commutation cell according to claim 11, wherein the conducting track is I-shaped in a region of the circuit carrier.

14. The commutation cell according to claim 11, wherein the conducting track is S-shaped in a region of the circuit carrier.

15. The commutation cell according to claim 11, wherein the commutation cell includes a shielding element which is formed between the current sensor and the conducting track.

16. The commutation cell according to claim 15, wherein the shielding element is formed by an electrically conductive layer of the flexible circuit board.

17. The commutation cell according to claim 15, wherein the current sensor is a differential Hall sensor including two sensor elements.

18. The commutation cell according to claim 17, wherein the conducting track includes two recesses adjacent to one another, and the shielding element includes recesses which correspond to recesses of the conducting track and which are arranged one above the other with the recesses of the conducting track, in an orthogonal projection.

19. The commutation cell according to claim 15, wherein signal lines routed to the sensor are shielded by the shielding element.

20. The commutation cell according to claim 16, wherein the shielding element is formed by an electrically conductive inner layer of the flexible circuit board, which is insulated from the conducting track and/or from the current sensor, by at least one or two electrically insulating layers surrounding it.
